(19) United States
(12) Patent Application Publication
(10) Pub. No.: US 2004/0008481 A1
(43) Pub. Date: Jan. 15, 2004

(54) Computer system and method of controlling the same

(75) Inventors: Sun-Hwa Han, Seoul City (KR); Kyoung-Won Kim, Yongin City (KR)

Correspondence Address: STAAS & HALSEY LLP, SUITE 700, 1201 NEW YORK AVENUE, N.W., WASHINGTON, DC, 20005, US

(73) Assignee: Samsung Electronics Co., LTD, Suwon City (KR)

(21) Appl. No.: 10/453,635

(22) Filed: Jun. 4, 2003

(30) Foreign Application Priority Data
Jul. 11, 2002 (KR) 2002-40495
Jan. 14, 2003 (KR) 2003-2484

(51) Int. Cl. H05K 5/00

(52) U.S. Cl. 361/683

(57) ABSTRACT

A method of controlling a computer system having an antenna capable of being drawn out and in, with which an automatic wireless network connection/disconnection can be made by drawing out/in the antenna. The present invention provides automatically wirelessly accessing and disconnecting to a computer system in one of system power states of powered, power-save and powered-off, by sensing whether the antenna is drawn out/in, and if sensed that the antenna is drawn out, converting the system into the powered state, if the system is in the state of power-save or powered-off, and executing/closing a network accessing program wirelessly accessing/disconnecting the network depending upon whether the antenna is drawn out/in, respectively.

### CROSS-REFERENCE TO RELATED APPLICATIONS

This application claims the benefit of Korean Application Nos. 2002-40495 filed Jul. 11, 2002 and 2003-2484 filed Jan. 14, 2003, in the Korean Intellectual Property Office, the disclosures of which are incorporated herein by reference.

### BACKGROUND OF THE INVENTION

1. Field of the Invention

The present invention relates in general to a computer system and a method of controlling the same, and more particularly, to a computer system having an antenna capable of being drawn outside or drawn into (retracted into) the computer system, with which it is allowed to wirelessly access and disconnect from a network system, thereby enabling the computer system to easily access and disconnect from the wireless network only by drawing out and in the antenna, and a method of controlling the computer system.

2. Description of the Related Art

According to developments of the networking environment, a network adaptor accessing a network has been an indispensable element in the configuration of a computer system. Especially, modules wirelessly accessing the network (wireless network accessing modules) have been employed in portable computers or personal digital assistants (PDAs), etc., whose portability has been considered important, so as to enable mobile wireless network access. Types of wireless network accessing modules may be a wireless LAN card for network access, a CDMA communication module for mobile network access, a Bluetooth module for short-distance wireless network access, etc.

In the case of accessing the network by means of the wireless network accessing module, a user can wirelessly access the network by executing software for network access. In other words, to wirelessly make a call or to access the Internet via the computer system, the user has to boot up the computer system and then execute the computer program for wirelessly accessing the Internet.

An antenna receiving and transmitting signals can be installed inside or outside the wireless network accessing module. In the case of an antenna mounted outside the module, typically the antenna is exposed on one side of the main body of the computer system, so as to allow the user to directly draw out the antenna at the time of wirelessly accessing the network.

Accordingly, to wirelessly access a network by a wireless network accessing module, the user has to execute application software for network access and has to draw out the antenna, thereby causing inconvenience in using the computer system.

Further, to wirelessly disconnect from the network, the user has to close (exit) the application software for network access and has to draw in the antenna, thereby causing inconvenience in using the computer system.

### SUMMARY OF THE INVENTION

Accordingly, the present invention provides a computer system allowing the user to wirelessly access and disconnect a network in a convenient and easy manner by only drawing out (extending) and drawing in (retracting) the antenna, and a method of controlling the computer system.

Additional aspects and advantages of the invention will be set forth in part in the description which follows and, in part, will be obvious from the description, or may be learned by practice of the invention.

The foregoing and/or other aspects of the present invention can be achieved by providing a method of controlling a computer system having an antenna capable of being drawn out and in, with which a wireless network connection can be made to receive and transmit data of the system in a wireless manner, comprising sensing whether the antenna is drawn out; and executing a network accessing program accessing a network, if the antenna is drawn out.

According to an aspect of the present invention, the method further comprises determining whether the system is in a power saving mode, if sensed that the antenna is drawn out; converting the system to a normal mode if determined that the system is in the power saving mode; and executing the network accessing program when the system is converted into the normal mode.

According to an aspect of the present invention, the method further comprises determining whether the system is turned off if sensed that the antenna is drawn out; supplying power to the system if determined that the system is turned off; booting up the system in response to the power supply to the system; and executing the network accessing program after the booting is completed.

According to an aspect of the invention, the execution of the network accessing program comprises accessing a previously specified wireless network.

According to an aspect of the invention, the method further comprises sensing whether the antenna is drawn in (retracted); and closing the executing network accessing program to disconnect from the network, if sensed that the antenna is drawn in.

The foregoing and/or other aspects of the present invention may be also achieved by providing a computer system having an antenna capable of being drawn out and in, with which a wireless network connection can be made to receive and transmit data of the system in a wireless manner, the computer system comprising an antenna sensing unit sensing drawing and retraction of the antenna; a system signal generating unit generating a system control signal controlling the system; and a controlling unit controlling the system signal generating unit to output a driving signal to a network accessing program accessing the network, if the antenna sensing unit senses that the antenna is drawn out.

According to an aspect of the present invention, the controlling unit controls the system signal generating unit to output the driving signal to the network accessing program after a power saving mode releasing signal is output, if sensed that the antenna is drawn out while the system is in the power saving mode.

According to an aspect of the present invention, the computer system further comprises a system power controlling unit supplying a driving power to the system; wherein the controlling unit controls the system signal generating unit to output the driving signal to the network accessing program after the driving power is supplied to the system by supplying a system power supply signal to the system power controlling unit through the system signal generating unit, if sensed that the antenna is pulled out while the system is turned off.

According to an aspect of the invention, the network accessing program accesses a previously specified wireless network when executed.

According to an aspect of the invention, the controlling unit controls the signal generating unit to generate a program close signal closing the network accessing program, if sensed that the antenna is retracted.

### BRIEF DESCRIPTION OF THE DRAWINGS

These and/or other aspects and advantages of the present invention will become apparent and more readily appreciated from the following description of the embodiments, taken in conjunction with the accompanying drawings of which:

FIG. 1 is a perspective view of a portable computer having a drawable antenna and operating according to an embodiment of the present invention;

FIG. 2 is a control block diagram of the computer system shown in FIG. 1, according to an embodiment of the present invention;

FIG. 3 is a control block diagram of the wireless network accessing module shown in FIG. 2, according to an embodiment of the present invention;

FIG. 4 is a flow chart of controlling the computer system shown in FIG. 1, according to one embodiment of the present invention; and

FIG. 5 is a flow chart of controlling the computer system shown in FIG. 1, according to another embodiment of the present invention.

### DETAILED DESCRIPTION OF THE PREFERRED EMBODIMENTS

Reference will now be made in detail to the present embodiments of the present invention, examples of which are illustrated in the accompanying drawings, wherein like reference numerals refer to the like elements throughout.

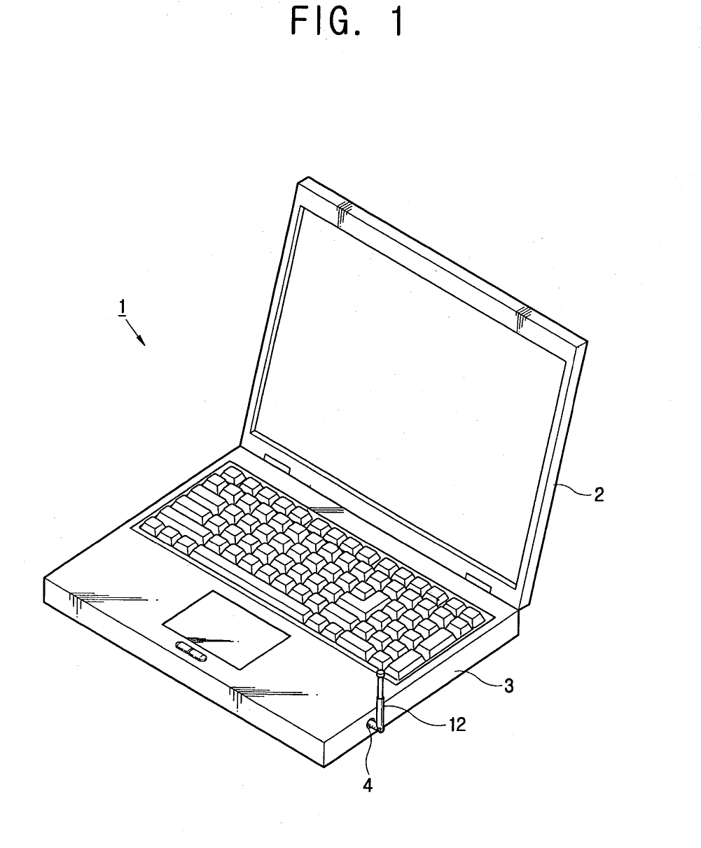

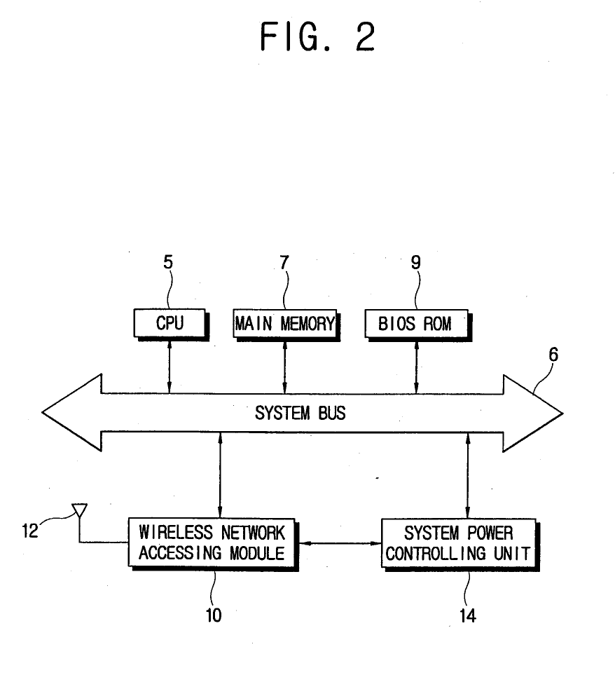

FIG. 1 is a perspective view of a portable computer having a drawable/extendable antenna (e.g., a telescopic antenna, retractable, etc.) and operating according to the present invention, and FIG. 2 is a control block diagram of the computer system shown in FIG. 1, according to an embodiment of the present invention. In FIG. 2, a portable computer 1 comprises a main body 3 and a display panel 2 hinge-coupled to the main body 3 so as to be opened in a foldable manner. Within the receiving space formed in the main body 3, as shown in FIG. 2, a variety of system components can be housed/installed, such as a central processing unit (CPU) 5, a main memory 7, a BIOS ROM 9, a system bus 6, a system power controlling unit 14, a wireless network accessing module 10 and so on.

Typically, the CPU 5, the main memory 7, the BIOS ROM 9, and the system bus 6 control operations of the computer system 1. In particular, the CPU 5 controls communication and processing of a variety of information through the system bus 6, by which functions of the computer system 1 are performed.

The system power controlling unit 14 supplies power to each component of the computer system 1 to drive them, according to a power selecting signal supplied, for example, after power selection by the user. The system power controlling unit 14 can also manage power supply to the computer system 1, such as power save modes.

The wireless network accessing module 10 wirelessly transmits and receives signals through a drawable and retractable antenna 12, thereby allowing the computer system 1 to wirelessly access a network (not shown), such as the Internet or an Intranet. Typically, the antenna 12 of the wireless network accessing module 10 is installed so as to be drawn outside through an opening 4 provided along a circumferential edge of the main body 3 to enhance receiving sensitivity. When the user tries to access the wireless network (i.e., wirelessly access the network), the user draws out the antenna 12 of the wireless network accessing module 10 through the opening 4 and extends the antenna 12 so as to be projected outside the main body 3, thereby enhancing the receiving and transmitting sensitivity of wireless signals. When the wireless network accessing module 10 is not driven (i.e., disconnected from the network), the user can use the computer system 1 with the antenna 12 received (retracted) within a receiving space of the main body 3. Typically, the antenna 12 is shaped like a telescopic tube and small, so that the antenna 12 can be received inside the main body 3. Further, the antenna 12 can be bent perpendicularly to a drawing direction in a state that the antenna 12 is drawn out through the opening 4 of the main body 3, thereby further enhancing the receiving and transmitting sensitivity for the wireless signal.

When the user tries to access the wireless network (i.e., wirelessly access the network), the user draws out the antenna 12 of the wireless network accessing module 10 through the opening 4 and extends the antenna 12 so as to be projected outside the main body 3, thereby enhancing the receiving and transmitting sensitivity of wireless signals. When the wireless network accessing module 10 is not driven, the user can use the computer system 1 with the antenna 12 received within a receiving space of the main body.

According to an aspect of the present invention, if the antenna 12 is drawn out, the wireless network accessible module 10 automatically outputs a signal driving (to start) a program wirelessly accessing the network, and the CPU 5 executes the program in response to the signal supplied from the wireless network accessing module 10.

According to an aspect of the present invention, if the antenna 12 is drawn out under a state that the computer system 1 is turned off or in a power save mode, the wireless network accessing module 10 supplies a power supply signal or a power save release signal to the system power controlling unit 14 and thereafter outputs the program driving signal to start the program wirelessly accessing the network. Accordingly, if the antenna 12 is drawn out when the system 1 is turned off or in the power save mode, the wireless network access program is executed after the computer system 1 is booted up. When the computer system 1 is in power states of power-off or power-save, the system power controller 14 supplies power to the network accessing module 10, allowing the module 10 to detect an operating state of the antenna 12 and generate control signals converting the power state of the computer system 1 to powered and executing a network access software establishing a wireless network access via the module 10 using the antenna 12.

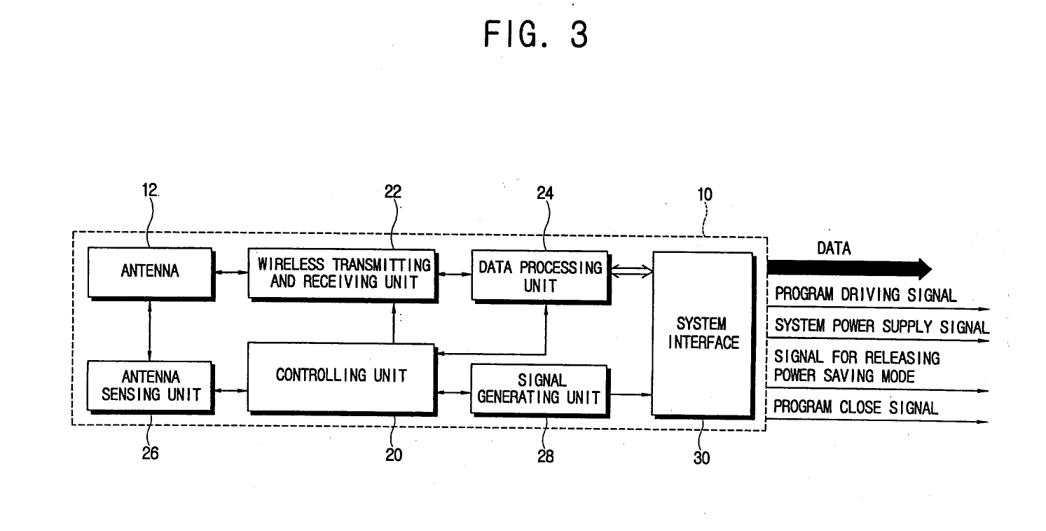

As shown in FIG. 2, the wireless network accessing module 10 as a processing component of the computer system 1 is in communication with other processing components of the computer system 1, such as the main memory 7, BIOS ROM 9, the system power controller 14, etc., via the system bus 6 using known techniques. Further, the network accessing module 10 can be directly in communication with a system power controlling unit 14 of the computer system 1. A configuration of the wireless network accessing module 10 shown in FIG. 2 will be described in more detail with reference to FIG. 3. In FIG. 3, the wireless network accessing module 10 comprises an antenna 12 receiving and transmitting wireless signals (data), a wireless transmitting and receiving unit 22, a data processing unit 24 processing the data transmitted and received, an antenna sensing unit 26 sensing drawing and retraction of the antenna 12, a signal generating unit 28 generating control signals relative to (i.e., processed by) the computer system 1, a controlling unit 20 controlling the units/components of the network accessing module 10, such as the units 22, 24 and 26 of the network accessing module 10, and a system interface 30 interfacing with the other processing components of the computer system 1 via the system bus 6 by receiving data and outputting data from/to the computer system 1.

The system interface 30 is an interface between the wireless network accessing module 10 and the computer system 1. Therefore, the data of the computer system 1 can be transmitted to the wireless network accessing module 10. Also, the computer system 1 can be supplied with data received through the wireless network accessing module 10 via the wireless signals generated in the wireless network accessing module 10. If the network accessing module 10 is implemented as a card (i.e., a printed circuit board/expansion board that can be interfaced with the computer system 1 for added capabilities), the system interface 30 may employ a PCI (peripheral component interconnect) interface, a PCMCIA (personal computer memory card international association) interface, a USB (universal serial bus) interface, etc. according to known methods of interfacing with the computer system 1. If the wireless network accessing module 10 is implemented on (i.e., integrated with) a system board of the computer system 1, it may be possible to obviate the system interface 30 and the module 10 may interface with the computer system 1 by directly exchanging data between the module 10 and the computer system 1 via the system bus 6.

The controlling unit 20 controls the wireless transmitting and receiving unit 22 and the data processing unit 24 to convert data input through the system interface 30 in a transmittable form for the network. The controlling unit 20 wirelessly transmits the converted data to the network through the wireless transmitting and receiving unit 22 and the antenna 12. Also, the controlling unit 20 processes data received from the network through the antenna 12, the wireless transmitting and receiving unit 22 and the data processing unit 24. The controlling unit 20 supplies the processed data from the network to the computer system 1.

According to an aspect of the present invention, the antenna sensing unit 26 senses drawing and retraction of the antenna 12 projected outside the main body 3 and supplies a sensed result to the controlling unit 20. Further, the controlling unit 20 controls the signal generating unit 28 to supply/generate system signals, such as a signal driving a network accessing program, a system power supply signal, a signal releasing power saving mode, a program close signal, etc., to the computer system 1 through the system interface 30.

If the antenna sensing unit 26 determines that the antenna 12 is drawn out, the controlling unit 20 controls the signal generating unit 28 to output the signal driving the network accessing program. The network accessing program driving signal generated through the signal generating unit 28 is transmitted to the system bus 6 and to the CPU 5 through the system interface 30, and the CPU 5 allows the network accessing program to be executed, in response to the network accessing program driving signal.

If the controlling unit 20 determines that the computer system 1 is in a power saving mode when the antenna 12 is drawn out, the controlling unit 20 generates the signal releasing the power saving mode through the signal generating unit 28 and outputs the releasing signal to the system power controlling unit 14, by which the computer system 1 is converted to the normal mode, and thereafter, the controlling unit 20 outputs the network accessing program driving signal to the computer system 1.

If the controlling unit 20 determines that the computer system 1 is turned off when the antenna 12 is drawn out, the controlling unit 20 first controls the signal generating unit 28 to output the system power supply signal to the system power controlling unit 14. The system power controlling unit 14 controls supply of power to circuitry of the computer system 1, in response to the system power supply signal from the wireless network accessing module 10, to thereby boot up the computer system 1. After the computer system 1 booting is completed, the controlling unit 20 generates the signal driving the network accessing program through the signal generating unit 28 and supplies the generated driving signal to the computer system 1, thereby enabling the network accessing program to be executed.

As described above, the controlling unit 20 of the wireless network accessing module 10 allows a network accessing program to be automatically executed in response to control signals from the module 10, if the antenna 12 is drawn out, thereby allowing the user to wirelessly access a network immediately through the network accessing program after drawing out the antenna 12.

In case the system 1 cannot directly execute the network accessing program because the computer system 1 is in the power saving mode or is turned off, the controlling unit 20 of the wireless network accessing module 10 first supplies a control signal appropriate for a state of the computer system 1, converting the computer system 1 to be in a state of driving (starting) the network accessing program. Accordingly, in a power saving mode, the controlling unit 20 first supplies the signal releasing the power saving mode to the computer system 1. In a state that the computer system is turned off, the controlling unit 20 supplies the system power signal to the computer system 1, converting the computer system 1 to be in a normal state. Once the computer system 1 is in a normal power state, the controlling unit 20 supplies the program driving signal to start a network accessing program.

As described above, the wireless network accessing module 10 comprises an antenna 12 capable of being drawn out and in, and some devices enabling access to a wireless network. The wireless network accessing module 10 may employ any known wireless protocols, such as a wireless LAN card, CDMA (cord-division multiple access) communication module, Bluetooth module, etc. Further, the wireless network accessing program can vary depending on the type of the wireless network accessing module 10. For example, if the wireless network accessing module 10 is a wireless LAN card, the network accessing program may be a web browser. If the wireless network accessing module 10 is a CDMA communication module, the network accessing program may be a phone communication program.

Here, the wireless network accessing program can be set up to automatically try to access a previously specified wireless network when the wireless network accessing program is executed (driven). For example, in case the wireless network accessing program is a web browser, the wireless network accessing module 10 can automatically try to access a specified web server as soon as the web browser is executed. In case the wireless network accessing program is the phone communication program, the wireless network accessing module 10 can automatically try to call a specified phone number. Thus, advantageously, a user can directly access the specified wireless network without any additional operations after the antenna 12 is drawn out or without any input commands to the computer system 1.

Further, the controlling unit 20 can control the signal generating unit 28 to generate the program close signal for closing the wireless network accessing program when the antenna sensing unit 26 senses that the antenna 12 is retracted inside the receiving space of the main body 3. The program close signal generated by the signal generating unit 28 is transmitted to the CPU 5 through the system interface 30 and the system bus 6, and the CPU 5 instructs the wireless network accessing program to be closed in response to the program close signal. Thus, advantageously, a user can close the wireless network accessing program without any additional operations after the antenna 12 is retracted or without any input commands to the computer system 1.

In the above-described embodiment, the computer system 1 equipped with the wireless network accessing module 10 and the system power controlling unit 14, according to the present invention, has been exemplified as the portable computer 1. However, the present invention can be employed in other types of computer systems, such as PDAs, palm top computers, desk top computers, etc., so long as they can wirelessly access a network with an extensible antenna 12.

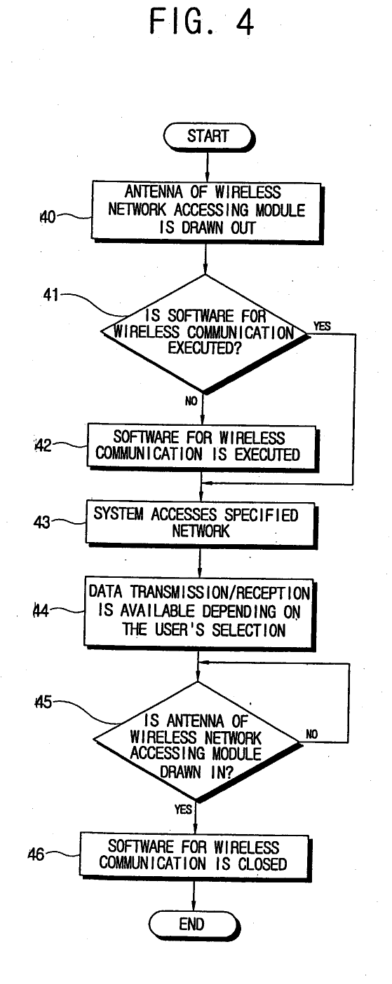

FIG. 4 is a flow chart of controlling the computer system 1 according to one embodiment of the present invention. In FIG. 4, for wirelessly accessing a network, at operation 40, a user draws out the antenna 12 of the wireless network accessing module 10. At operation 40, the controlling unit 20 of the wireless network accessing module 10 senses through the antenna sensing unit 12 whether the antenna 12 has been drawn out. If, at operation 40, it is sensed that the antenna 12 has been drawn out, at operation 41, the controlling unit 20 determines whether the network accessing program for wireless communication is executed (i.e., already running).

If, at operation 41, the network accessing program for wireless communication is not executing, the controlling unit 20 of the wireless network accessing module 10 supplies a signal driving (starting) the network accessing program through the signal generating unit 28. If, at operation 41, the driving signal for the network accessing program is supplied by the controlling unit 20 through the signal generating unit 28 to the CPU 5, at operation 42, the CPU 5 commences to execute the network accessing program. If, at operation 41, or after operation 42, the network accessing program is executing, at operation 43, the user can wirelessly access a specified wireless network using the executing wireless network accessing program, and, at operation 44, data transmission and reception is performed. Thereafter, at operation 45, it is determined (monitor) whether the antenna 12 of the wireless network accessing module 10 is retracted by the user to disconnect the wireless network. In particular, at operation 45, the controlling unit 20 of the wireless network accessing module 10 senses that the antenna 12 has been drawn in (retracted), using the antenna sensing unit 26, and, at operation 46, controls the signal generating unit 28 to generate a program close signal closing the network accessing program, thereby disconnecting the wireless network.

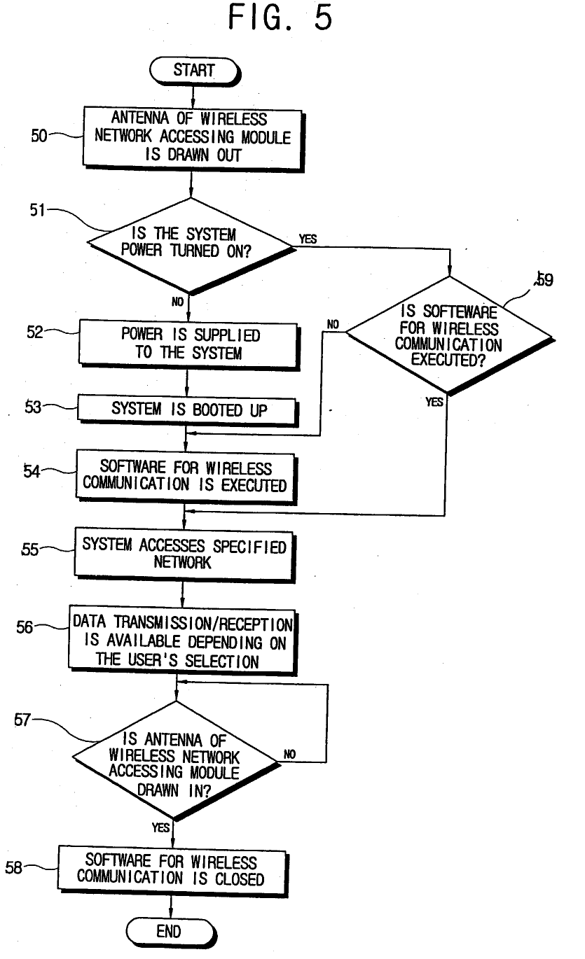

FIG. 5 is a flow chart of controlling the computer system 1 if the network accessing program cannot be directly executed by the computer system 1. If, at operation 50, the antenna 12 of the wireless network accessing module 10 is drawn out by the user, the controlling unit 20 of the wireless network accessing module 10 senses through the antenna sensing unit 26 whether the antenna 12 is drawn out, and, at operation 51, determines whether the computer system 1 is turned on or off using the system power controlling unit 14.

If, at operation 51, the computer system 1 is turned on, at operation 59, the controlling unit 20 of the wireless network accessing module 10 determines whether the network accessing program for wireless communication is executing. If, at operation 59, the network accessing program is not executing, at operation 54, the controlling unit 10 supplies a signal driving the network accessing program to have the network accessing program executed. If, at operation 59, the network accessing program is executing, at operation 55, the computer system 1 can access a specified network.

If, at operation 51, the computer system 1 is turned off, at operation 52, the controlling unit 20 of the wireless network accessing module 10 first outputs a system power supply signal for power supply to the computer system 1 (for example, outputs a system power supply signal to the system power controlling unit 14). At operation 53, the computer system 1 is booted up, in response to the power supply. At operation 54, the controlling unit 20 supplies a signal driving the network accessing program to have the network accessing program executed. When the network accessing program is executed, at operation 55, the user can wirelessly access a specified network using the wireless network accessing program, and, at operation 56, data reception and transmission is performed. Thereafter, at operation 57, it is determined (monitor) whether the antenna 12 of the wireless network accessing module 10 is retracted by the user to disconnect the wireless network. More particularly, at operation 57, the controlling unit 20 of the wireless network accessing module 10 senses that the antenna 12 has been retracted, using the antenna sensing unit 26, and, at operation 58, controls the signal generating unit 28 to generate a program close signal closing the network accessing program, thereby disconnecting the wireless network.

The control flow as described above in FIG. 5 can be applied in the same manner if the computer system is in a power saving mode under which the network accessing program cannot be directly executed by the computer system 1. If the computer system 1 is in the power saving mode, operation 51 determines whether the computer system 1 is in the power saving mode. Further, at operation 52, the controlling unit 20 would supply a signal releasing the power saving mode to the computer system 1 (for example, outputs the release signal, directly, or indirectly via the bus 6, to the system power controlling unit 14). Further, at operation 53, power management of the computer system 1 would be converted from the power saving mode into the normal mode.

Accordingly, if the computer system 1 is in a state that the network accessing program cannot be executed directly, the controlling unit 20 of the wireless network accessing module 10 first supplies a signal corresponding to a state of the system 1 (i.e., converting the computer system 1 to be in a state) in which the network accessing program can be executed, and thereafter allowing/instructing the network accessing program to be executed.

As described above, according to the present invention, there is provided a computer system having an antenna capable of being drawn out and in, enabling a wireless access and disconnect to a network. In this computer system, if the antenna is drawn out, the network accessing program is automatically executed. If the network accessing program cannot be directly executed, the computer system is converted into a normal state, and thereafter, the network accessing program is automatically executed. Accordingly, the user can access the wireless network without any additional operations after the antenna is drawn out or without any input commands. Further, if the antenna is retracted, the wireless network accessing program is automatically closed. Accordingly, the user can close the wireless network accessing program without any additional operations after the antenna is retracted or without any input commands to the computer system. Therefore, as described thus far, according to the present invention, there is provided a computer system accessing and disconnecting to a wireless network in an easy manner, simply by drawing out and in the antenna within the computer system, and a method of controlling the computer system.

More particularly, the present invention provides a computer system having an antenna capable of being drawn out and in, with which drawing out/extending and retracting the antenna can make an automatic wireless network connection and disconnection, respectively. The present invention provides automatically wirelessly accessing and disconnecting a wireless network to a computer system, thereby receiving and transmitting data to/from the computer system over the wireless network, in one of system power states of powered, power-save and powered-off, by sensing whether the antenna is drawn out or retracted. If the antenna is drawn out, the system is converted into the powered state, if the system is in one of the power states of power-save and powered-off, and the system executes a network accessing program wirelessly accessing the network. Conversely, if the antenna is retracted, the system automatically closes (exits) the network accessing program, disconnecting the wireless network.

The processes of the present invention as embodied in the wireless network module 10 and the system power controlling unit 14 can be implemented in software and/or hardware. Further, although the example embodiment uses a drawable/extendable and retractable antenna, the present invention is not limited to such configuration. The extendable and retractable antenna can be any wireless signal sensor (e.g., radio, light wave) or device radiating and receiving radio/light waves (i.e., for transmitting and receiving wireless signals) that can accommodate sensing of an on/off (operating) state of the device. For example, a snap in/out type, switchable, or fastened type device can be used in the invention or any device that allows sensing of a state of electrical contact/no electrical contact to the device can be used.

Although an embodiment of the present invention has been shown and described, it will be appreciated by those skilled in the art that changes may be made in this embodiment without departing from the principles and spirit of the invention, the scope of which is defined in the appended claims and their equivalents.

What is claimed is:

1. A method controlling a computer system having a retractable antenna to access a wireless network to wirelessly receive and transmit data of the system, comprising:
sensing whether the antenna is drawn out; and
executing a network accessing program accessing the network, if sensed that the antenna is drawn.

2. The method according to claim 1, further comprising:
determining whether the system is in a power saving mode, if sensed that the antenna is drawn out;
converting the system to a normal mode, if determined that the system is in the power saving mode; and
executing the network accessing program when the system is converted into the normal mode.

3. The method according to claim 1, further comprising:
determining whether the system is turned off, if sensed that the antenna is drawn out;
supplying power to the system, if determined that the system is turned off;
booting up the system in response to the power supply to the system; and
executing the network accessing program after the booting is completed.

4. The method according to claim 1, wherein the executing of the network accessing program comprises accessing a previously specified wireless network.

5. The method according to claim 1, further comprising:
sensing whether the antenna is drawn in; and
closing the executing network accessing program accessing the network, if sensed that the antenna is drawn in.

6. A computer system having a retractable antenna to access a wireless network to wirelessly receive and transmit data of the system, comprising:
an antenna sensing unit sensing drawing and retracting of the antenna;
a system signal generating unit generating a system control signal controlling the system; and
a controlling unit controlling the system signal generating unit to output a driving signal to a network accessing program accessing the network, if the antenna sensing unit senses that the antenna is drawn out.

7. The computer system according to claim 6, wherein the controlling unit controls the system signal generating unit to output the driving signal to the network accessing program after a power saving mode releasing signal is output, if sensed that the antenna is drawn while the system is in the power saving mode.

8. The computer system according to claim 6, further comprising a system power controlling unit supplying a driving power to the system;
wherein the controlling unit controls the system signal generating unit to output the driving signal to the network accessing program, after the driving power is supplied to the system by supplying a system power supply signal to the system power controlling unit through the system signal generating unit, if sensed that the antenna is drawn while the system is turned off.

9. The computer system according to claim 6, wherein the network accessing program accesses a previously specified wireless network.

10. The computer system according to claim 6, wherein the controlling unit controls the signal generating unit to generate a program close signal closing the network accessing program, if sensed that the antenna is drawn in.

11. A method of controlling wireless network access and disconnect of a computer, comprising extending and retracting an antenna to automatically wirelessly connect and disconnect, respectively, to the network in one of computer power states of powered, power-save and powered-off.

12. A wireless network controller to wirelessly access a network and in communication with a computer having a power manager, the controller comprising:
a wireless signal sensor;
a detector detecting an operating state of the sensor; and
a programmed computer processor determining a power state of the computer in response to a detected operating state of the sensor, determining execution status of network access software in the computer, generating control signals to the power manager of the computer to start the network access software in response to the power state of the computer and the execution status of the network access software, and controlling wireless data communication between the network and the executing network access software.

13. The controller of claim 12, wherein the detector detects a non-operating state of the sensor and the programmed computer processor generates a network access software close signal to disconnect from the network.

14. A computer system, comprising:
a wireless network controller comprising a wireless signal sensor and a programmed computer processor generating control signals in one of computer power states of powered, power-save and power-off to automatically execute a network access software to establish a wireless network access, in response to an operating state of the wireless signal sensor.

15. The computer system of claim 14, further comprising:
a power manager supplying power to the wireless network controller in the computer power states of power-save and power-off,
wherein the power manager converts the computer system into the powered state by supplying power to the computer system in the power states of power-save or power-off in response to one of the control signals and the powered computer system executes the network access software in response to another of the control signals.

16. A computer system, comprising:
sensing means for sensing wireless signals;
detecting means for detecting an operating state of the sensing means;
control signal generating means for generating signals to automatically execute a network access software in response to the operating state of the sensing means; and
wireless network protocol means for wirelessly exchanging data between a wireless network and the computer via the sensing means.

17. The computer system of claim 16, wherein the detecting means further detects a non-operating state of the sensing means and the control signal generating means generates a network access software close signal to disconnect the wireless network.

18. A network access controller in a computer, the controller comprising:
a wireless signal sensor; and
a programmed computer processor detecting an operating state of the sensor, generating control signals in one of the computer power states of powered, power-save and power-off to automatically execute a network access software to establish a wireless network access, in response to the detected operating state of the sensor.

19. The controller of claim 18, wherein the programmed computer processor further detects a non-operating state of the sensor, and generates a network access software close signal to disconnect the wireless network.
